(19) United States
(12) Patent Application Publication
(10) Pub. No.: US 2015/0187948 A1
(43) Pub. Date: Jul. 2, 2015

(54) SEMICONDUCTOR DEVICE AND METHOD FOR PRODUCING SAME

(71) Applicant: Sharp Kabushiki Kaisha, Osaka-shi, Osaka (JP)

(72) Inventor: Katsunori Misaki, Yonago-shi (JP)

(21) Appl. No.: 14/417,232

(22) PCT Filed: Jul. 19, 2013
(86) PCT No.: PCT/JP2013/069677

§ 371 Date: Jan. 26, 2015

(30) Foreign Application Priority Data
Jul. 27, 2012 (JP) 2012-166705

(51) Int. Cl. H01L 29/786; H01L 29/66; H01L 21/441; H01L 21/02; H01L 21/477; H01L 29/45; H01L 29/24

(52) U.S. Cl. CPC H01L 29/7869; H01L 29/78618; H01L 29/45; H01L 29/66969; H01L 29/24; H01L 21/02565; H01L 21/477; H01L 21/441; H01L 21/0217; H01L 21/02164; H01L 21/02274

(57) ABSTRACT

This semiconductor device (100) includes: a gate electrode (12) formed on a substrate (10); a gate insulating layer (20) formed over the gate electrode; an oxide semiconductor layer (18) formed on the gate insulating layer; source and drain electrodes (14, 16) connected to the oxide semiconductor layer; and an insulating layer (22) formed over the source and drain electrodes. The insulating layer includes a silicon nitride layer (22a) which contacts with at least a part of the upper surface of the source and drain electrodes and of which the thickness is greater than 0 nm and equal to or smaller than 30 nm, and a silicon oxide layer (22b) which has been formed on the silicon nitride layer and which has a thickness of more than 30 nm.

### TECHNICAL FIELD

The present invention relates to a semiconductor device (such as an active-matrix substrate) which is formed with an oxide semiconductor, and also relates to a method for producing such a device.

### BACKGROUND ART

An active-matrix substrate for use in a liquid crystal display device and other devices includes switching elements such as thin-film transistors (which will be hereinafter simply referred to as “TFTs”), each of which is provided for an associated one of pixels. As such switching elements, a TFT which uses an amorphous silicon film as its active layer (and will be hereinafter referred to as an “amorphous silicon TFT”) and a TFT which uses a polysilicon film as its active layer (and will be hereinafter referred to as a “polysilicon TFT”) have been used extensively.

Recently, people have proposed that a material other than amorphous silicon or polysilicon be used as a material for the active layer of a TFT. For example, Patent Document No. 1 discloses a liquid crystal display device, of which the TFT's active layer is formed out of an oxide semiconductor film of InGaZnO (that is an oxide made up of indium, gallium and zinc). Such a TFT will be hereinafter referred to as an “oxide semiconductor TFT”.

The oxide semiconductor TFT can operate at higher speeds than an amorphous silicon TFT. Also, such an oxide semiconductor film can be formed by a simpler process than a polysilicon film, and therefore, is applicable to even a device that needs to cover a large area. That is why an oxide semiconductor TFT has been used more and more often in a display device and other devices as an active element which achieves even higher performance in its switching operation and which can be fabricated with the number of manufacturing process steps and the manufacturing cost cut down.

In addition, since an oxide semiconductor has high electron mobility, even an oxide semiconductor TFT of a smaller size than a conventional amorphous silicon TFT could achieve performance that is equal to or higher than that of the amorphous silicon TFT. For that reason, by using oxide semiconductor TFTs, the area occupied by the TFT in a pixel region of a display device or any other device can be decreased, and therefore, the aperture ratio of the pixel can be increased. Consequently, a display operation can be performed with even higher luminance or the power dissipation can be reduced by decreasing the quantity of light emitted from a backlight.

For example, in a small-sized high-definition liquid crystal display device for use in a smartphone and other electronic devices, it is not easy to increase the aperture ratio of a pixel due to the limit on the minimum width of lines (i.e., the process rule). That is why if the aperture ratio of the pixel can be increased by using an oxide semiconductor TFT, a high-definition display operation can be carried out with the power dissipation cut down, which is advantageous.

### CITATION LIST

### Patent Literature

Patent Document No. 1: PCT International Application Publication No. 2009/075281

Patent Document No. 2: Japanese Laid-Open Patent Publication No. 2009-117821

### SUMMARY OF INVENTION

### Technical Problem

In its manufacturing process, an oxide semiconductor TFT is usually subjected to a heat treatment at a relatively high temperature (e.g., about 300° C. or more) in order to improve the performance of the device. This heat treatment is often carried out after a passivation layer (protective layer) has been formed to cover the oxide semiconductor layer and source and drain electrodes. If the source and drain electrodes are covered with the passivation layer, it is possible to prevent their surface from being oxidized and coming to have increased resistance during the heat treatment.

Examples of known passivation layers for use in an oxide semiconductor TFT include a silicon oxide (SiOx) film, a silicon oxynitride (SiOxNy, where x>y) film, a silicon nitride oxide (SiNxOy, where x>y) film and a silicon nitride (SiNx) film. Meanwhile, Patent Document No. 2 discloses a technique for forming a passivation layer with a multilayer structure by alternately stacking an insulator including nitrogen such as silicon oxynitride and an insulator including nitrogen and fluorine one upon the other.

Such a passivation layer that has been formed to cover TFTs sometimes includes hydrogen at a relatively high percentage. For example, if a silicon nitride (SiNx) film is formed by CVD process using SiH₄ (mono-silane) gas and NH₃ gas as source gases, then hydrogen will be included at a relatively high percentage in the silicon nitride film formed. If the heat treatment described above is carried out with such an insulating film including a lot of hydrogen provided, then the hydrogen will diffuse inside the oxide semiconductor layer and sometimes cause deterioration in the performance of TFTs.

The present inventors perfected our invention in order to overcome these problems by providing high-performance semiconductor devices with good stability and at a good yield.

### Solution to Problem

A semiconductor device according to an embodiment of the present invention includes: a substrate; a gate electrode which has been formed on the substrate; a gate insulating layer which has been formed over the gate electrode; an oxide semiconductor layer which has been formed on the gate insulating layer; source and drain electrodes which are electrically connected to the oxide semiconductor layer; and an insulating layer which has been formed over the source and drain electrodes. The insulating layer includes a silicon nitride layer which contacts with at least a part of the upper surface of the source and drain electrodes and of which the thickness is greater than 0 nm and equal to or smaller than 30 nm, and a silicon oxide layer which has been formed on the silicon nitride layer and of which the thickness is greater than 30 nm.

In one embodiment, the silicon oxide layer has a thickness of 50 nm to 400 nm.

In one embodiment, the upper surface of the source and drain electrodes that contacts with the silicon nitride layer is made of a conductive material including at least one element selected from the group consisting of Mo, Ti, Cu and Al.

In one embodiment, the contact surface of the source and drain electrodes is made of molybdenum nitride.

In one embodiment, the semiconductor device further includes an etch stop layer which has been formed over a channel region of the oxide semiconductor layer.

In one embodiment, the oxide semiconductor layer is made of an In—Ga—Zn—O based semiconductor.

A method for fabricating a semiconductor device according to an embodiment of the present invention includes the steps of: (a) providing a substrate; (b) forming a gate electrode on the substrate; (c) forming an oxide semiconductor layer over the substrate so that the oxide semiconductor layer is insulated from the gate electrode and faces the gate electrode; (d) forming source and drain electrodes to be connected to the oxide semiconductor layer on the substrate; (e) forming an insulating layer which contacts with at least a part of the upper surface of the source and drain electrodes over the substrate; and (f) conducting a heat treatment at a temperature of 230° C. to 480° C. after the step (e) has been performed. The step (e) includes the steps of: forming a first insulating region including nitrogen so that the first insulating region contacts with the source and drain electrodes and has a thickness of more than 0 nm to equal to or smaller than 30 nm; and forming a second insulating region including oxygen over the first insulating region so that the second insulating region has a thickness of more than 30 nm.

In one embodiment, the first insulating region is formed out of a silicon nitride layer and the second insulating region is formed out of a silicon oxide layer.

In one embodiment, the step (d) includes forming the surface of the source and drain electrodes out of a conductive material including at least one element selected from the group consisting of Mo, Ti, Cu and Al.

In one embodiment, the step of forming the silicon nitride layer in the step (e) is performed by a plasma CVD process using source gases including SiH₄ and NH₃ gases.

### Advantageous Effects of Invention

A semiconductor device according to an embodiment of the present invention contributes to fabricating a TFT substrate including oxide semiconductor TFTs with good device performance at a good yield.

### BRIEF DESCRIPTION OF DRAWINGS

FIG. 1 (a) and (b) are cross-sectional views illustrating TFT substrates as comparative examples.

FIG. 2 A plan view illustrating a TFT substrate as a first embodiment.

FIG. 3 (a) and (b) are cross-sectional views taken along lines A-A′ and D-D′ in FIG. 2 respectively.

FIG. 4 (a) through (e) are cross-sectional views illustrating respective manufacturing process steps to fabricate the TFT substrate of the first embodiment.

FIG. 5 (f) through (i) are cross-sectional views illustrating respective manufacturing process steps to fabricate the TFT substrate of the first embodiment.

FIG. 6 (j) through (l) are cross-sectional views illustrating respective manufacturing process steps to fabricate the TFT substrate of the first embodiment.

FIG. 7 A plan view illustrating a TFT substrate as a second embodiment.

FIG. 8 (a) and (b) are cross-sectional views taken along lines A-A′ and D-D′ in FIG. 7.

FIG. 9 (a) through (e) are cross-sectional views illustrating respective manufacturing process steps to fabricate the TFT substrate of the second embodiment.

FIG. 10 (f) through (j) are cross-sectional views illustrating respective manufacturing process steps to fabricate the TFT substrate of the second embodiment.

### DESCRIPTION OF EMBODIMENTS

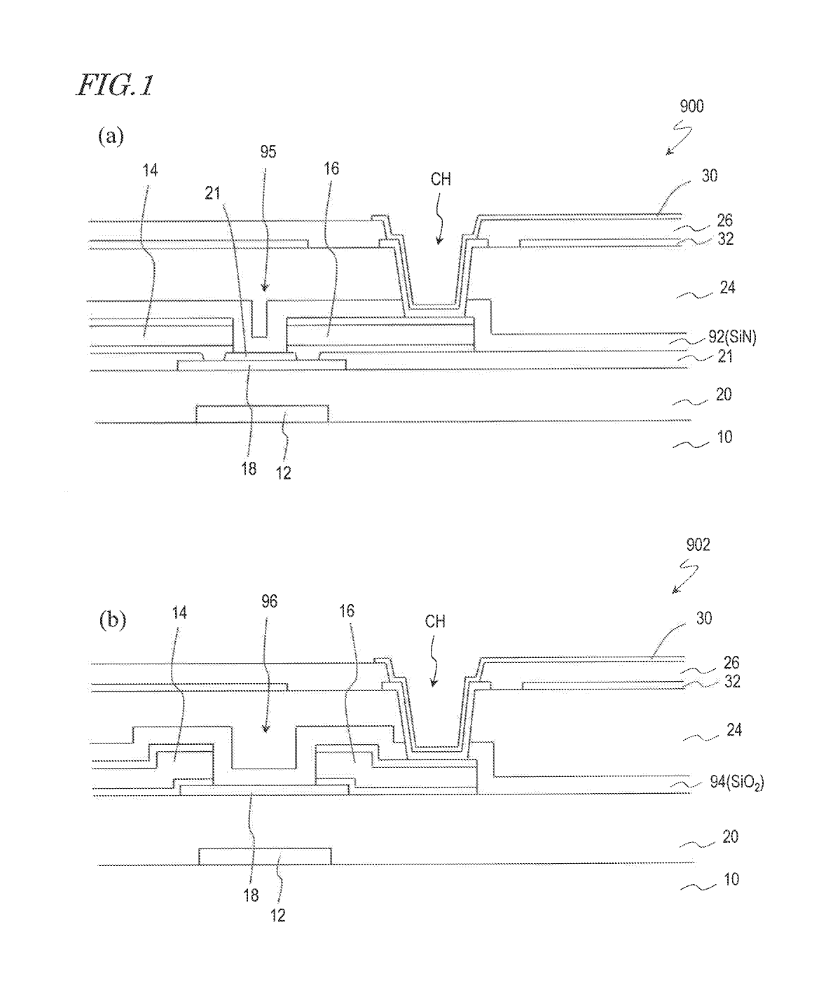

First of all, a semiconductor device according to an embodiment of the present invention will be outlined with reference to semiconductor devices as comparative examples shown in FIGS. 1(a) and 1(b).

FIG. 1(a) illustrates a semiconductor device 900 as a first comparative example (which is a TFT substrate for use in a liquid crystal display device in this example). The TFT substrate 900 includes a substrate 10, on which an oxide semiconductor layer 18 is arranged with a gate electrode 12 and a gate insulating film 20 interposed between them so as to overlap with the gate electrode 12. Source and drain electrodes 14 and 16 are connected to the oxide semiconductor layer 18. These members together form a TFT (oxide semiconductor TFT) 95. The TFT 95 is covered with a passivation layer 92 which is provided as a protective layer. The TFT substrate 900 further includes an upper transparent electrode 30 which is connected to the drain electrode 16 of the TFT 95 and a lower transparent electrode 32 which is arranged under the upper transparent electrode 30 with a dielectric layer 26 interposed between them. However, description thereof will be omitted herein.

In this TFT substrate 900, the passivation layer 92 is formed out of an SiNx (silicon nitride) film and typically has a thickness of 100 to 400 nm. An SiNx film is dense enough to protect the TFT 95 effectively.

However, if the passivation layer 92 is formed out of a silicon nitride film, hydrogen included in the silicon nitride film sometimes diffuses toward the oxide semiconductor layer 18 during a heat treatment process, for example. Particularly when a silicon nitride film which has been formed using SiH₄ (mono-silane) and NH₃ gases as source gases is used, that film includes hydrogen at a relatively high percentage, and therefore, hydrogen will enter the oxide semiconductor layer 18 easily.

That hydrogen affects the channel region of the oxide semiconductor layer 18 (on the back channel side). As a result, when the module fabricated goes through an aging treatment, its threshold value will shift (i.e., the TFT performance will vary). That is why if a display panel is fabricated using the TFT substrate 900, the display quality of the panel deteriorates due to generation of off-state leakage current or shortage of on-state current. For that reason, diffusion of hydrogen into the oxide semiconductor layer 18 should be reduced as much as possible.

To overcome such a problem, according to a known configuration, an insulating layer (etch stop layer) 21 is arranged under the source and drain electrodes 14, 16 so as to cover the channel region of the oxide semiconductor layer 18 as shown in FIG. 1(a). In the process step of forming the source and drain electrodes 14, 16 by etching a conductive film, the etch stop layer 21 works to prevent the oxide semiconductor layer 18 from getting etched. Also, if the etch stop layer 21 is made of an oxide (such as SiO₂), diffusion of hydrogen from the passivation layer 92 to the oxide semiconductor layer 18 can be minimized. As a result, the reduction reaction of the oxide semiconductor layer 18 can be reduced on the back channel side, and therefore, deterioration of the TFT performance can be minimized. Such a configuration including an etch stop layer 21 is called a “channel protected type (or etch stop type)” as will be described later.

However, even if such a channel-protected TFT 95 is formed, the passivation layer 92 should not include a lot of hydrogen, because that will cause deterioration in the performance of the device. In addition, if the etch stop layer 21 needs to be provided, an additional manufacturing process step should be performed for that purpose, which is also a problem.

Thus, to overcome such a problem, it was proposed that the passivation layer 94 be made of a material that would affect the oxide semiconductor layer 18 to a lesser degree as in a second comparative example shown in FIG. 1(b). For example, the passivation layer 94 may be made of an oxide film such as an SiO₂ film. Such an idea of making the protective layer of an oxide semiconductor TFT of an oxide is disclosed in Patent Document No. 1, for example.

As shown in FIG. 1(b), in the TFT substrate 902 of the second comparative example, the passivation layer 94 is made of an SiO₂ film, and therefore, no etch stop layer is provided to cover the channel region of the oxide semiconductor layer 18. That is to say, in this TFT substrate 902, not the channel-protected TFTs described above but “channel-etched” TFTs 96 (to be described later) have been formed.

However, the present inventors discovered and confirmed via experiments that when the passivation layer 94 was formed out of an oxide film such as an SiO₂ film, the surface of the source and drain electrodes 14, 16 got oxidized easily during the heat treatment process to be carried out after that. This is because an oxidation reduction reaction would occur between the metal and the oxide film at the interface between the source and drain electrodes 14, 16 and the passivation layer 94. If an oxide film has been formed on the surface of the source and drain electrodes 14, 16 in this manner, the closeness of contact of the passivation layer 94 sometimes decreases. As a result, the passivation layer 94 might peel off in a subsequent process step, thus causing a decrease in yield.

Particularly if the surface of the source and drain electrodes 14, 16 is made of a metallic material (such as MoN) including Mo, Ti, Cu or Al and if a metal oxide film is formed on the surface, the SiO₂ film will peel off easily from the surface of the source and drain electrodes 14, 16.

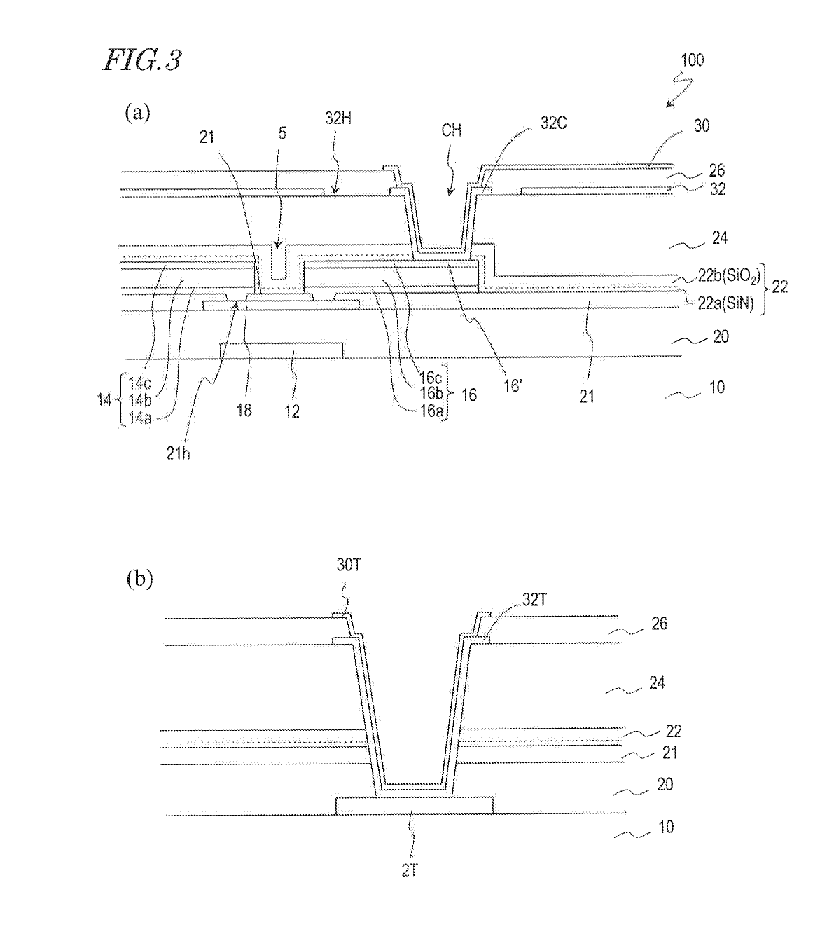

Thus, to overcome such a problem, the present inventors carried out intensive researches. As a result, the present inventors discovered that a thin silicon nitride layer (such as an SiN film) 22a with a thickness of 30 nm or less should be provided so as to contact with the surface of the source and drain electrodes 14, 16 and a silicon oxide layer (such as an SiO₂ film) 22b should be provided on the silicon nitride layer 22a as shown in FIG. 3(a).

According to such a configuration, the passivation layer 22 as a whole includes so little hydrogen that the influence on the oxide semiconductor layer 18 and deterioration of the TFT performance can be reduced. In addition, since no oxide film is arranged directly on the source and drain electrodes 14, 16, it is possible to prevent the surface of the source and drain electrodes 14, 16 from getting oxidized and losing closeness of contact during the heat treatment. The present inventors discovered that the decrease in the closeness of contact of the passivation layer 22 could be checked sufficiently just by interposing a thin silicon nitride layer with a thickness of as small as 30 nm or less. As a result, the occurrence of film peeling due to a decrease in the closeness of contact of the passivation layer 22 could be prevented with the device performance of the oxide semiconductor TFT kept high.

A semiconductor device as an embodiment of the present invention and a method for fabricating that device will now be described. A semiconductor device according to an embodiment of the present invention just needs to include a thin-film transistor with an active layer made of an oxide semiconductor (which will be hereinafter referred to as an “oxide semiconductor TFT”). The semiconductor device is broadly applicable to an active-matrix substrate and various kinds of display devices and electronic devices.

In the following description, an oxide semiconductor TFT with a bottom-gate structure, in which a gate electrode is arranged under an oxide semiconductor layer, will be described. In an oxide semiconductor TFT with a bottom-gate structure, source and drain electrodes are ordinarily formed by etching a conductive layer which has been formed on the oxide semiconductor layer (in a source/drain dividing process step). In this process step, to minimize the damage to be done on the oxide semiconductor layer through etching, the conductive layer may be etched with the channel region of the oxide semiconductor layer covered with a protective film (i.e., the etch stop layer 21 described above). A TFT thus obtained will be hereinafter referred to as a “channel-protected type (or etch stop type)”. On the other hand, a TFT to be obtained by etching a conductive layer without covering the channel portion with a protective film will be hereinafter referred to as a “channel-etched type”.

In the following description, a semiconductor device including a TFT of the channel-protected type will be described as a first embodiment, and a semiconductor device including a TFT of the channel-etched type will be described as a second embodiment.

### embodiment 1

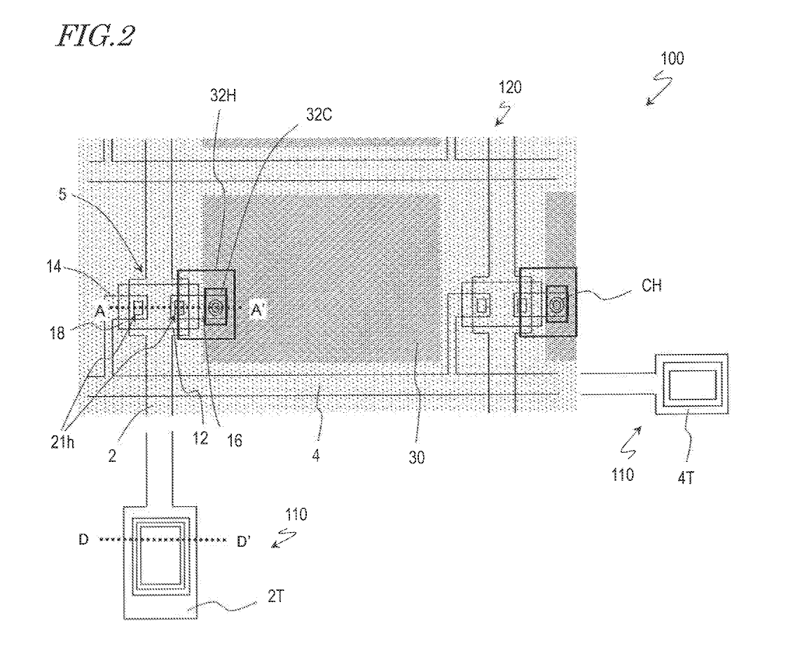

FIG. 2 and FIGS. 3(a) and 3(b) illustrate a semiconductor device 100 as a first embodiment. In this embodiment, the semiconductor device 100 is implemented as a TFT substrate (active-matrix substrate) 100 for use in a liquid crystal display device. FIG. 2 schematically illustrates a planar structure of the TFT substrate 100, and FIGS. 3(a) and 3(b) illustrate cross-sections as respectively viewed on the planes A-A′ and D-D′ shown in FIG. 2.

As shown in FIG. 2, this TFT substrate 100 includes a display area (active area) 120 which contributes to a display operation and a peripheral area (frame area) 110 which is located outside of the display area 120.

In the display area 120, a plurality of gate lines 2 and a plurality of source lines 4 have been formed, and each region surrounded with these lines defines a “pixel”. Those pixels are arranged in a matrix pattern. In each pixel, a thin-film transistor (TFT) 5 is arranged as an active element in the vicinity of each intersection between the gate lines 2 and the source lines 4. Each TFT 5 is electrically connected to its associated pixel electrode 30 provided for each pixel. By controlling the voltage applied to the pixel electrode 30, a display operation can be performed.

In the peripheral area 110, terminal portions 2T, 4T, each of which electrically connects either a gate line 2 or a source line 4 to an external line, have been formed. The gate line terminal portion 2T and source line terminal portion 4T are respectively connected to a gate driver and a source driver (neither is shown) which are provided outside of the TFT substrate 100 via an external line and an FPC.

Next, the configuration of the TFT substrate 100 in the vicinity of the TFT 5 will be described with reference to FIG. 3(a).

As shown in FIG. 3(a), the TFT substrate 100 includes, on a substrate 10, a gate electrode 12, a gate insulating layer 20 which covers the gate electrode 12, and an oxide semiconductor layer (such as an In—Ga—Zn—O based semiconductor layer) 18 which is arranged so as to overlap with the gate electrode 12 with the gate insulating layer 20 interposed between them. An etch stop layer 21 has been formed on the oxide semiconductor layer 18. Through the holes 21h that have been cut through the etch stop layer 21, source and drain electrodes 14 and 16 are connected to the oxide semiconductor layer 18 so as to be separated from each other. A TFT 5 is formed of these members. When an ON-state voltage is applied to the gate electrode 12, the TFT 5 turns ON, and the source and drain electrodes 14, 16 get electrically conductive with each other via the channel region of the oxide semiconductor layer 18.

In this embodiment, the source and drain electrodes 14, 16 have a triple layer structure consisting of MoN, Al and MoN layers. The lowermost MoN layer 14a, 16a contacts with the oxide semiconductor layer 18. An Al layer 14b, 16b is provided as a middle layer. And the uppermost MoN layer 14c, 16c arranged on the Al layer forms the surface of the source and drain electrodes 14, 16, and contacts with a passivation layer 22 to be described later.

A passivation layer 22 has been formed as a protective insulating layer which covers the TFT 5. The passivation layer 22 is comprised of a lower insulating layer 22a which is arranged so as to contact with the source and drain electrodes 14, 16 (more specifically, their uppermost

MoN layer 14c, 16c) and an upper insulating layer 22b arranged on the lower insulating layer 22a. In this embodiment, the lower insulating layer 22a is formed out of a silicon nitride (SiNx) layer with a thickness of more than 0 nm to equal to or smaller than 30 nm, and the upper insulating layer 22b is formed out of a silicon oxide (SiOx) layer with a thickness of more than 30 nm.

The lower insulating layer 22a is formed out of a silicon nitride layer, and therefore, typically includes some hydrogen. However, the thickness of this lower insulating layer 22a falls within the range of 0 to 30 nm as described above, and is much smaller than that of an ordinary passivation layer 22 (which usually falls within the range of 100 to 400 nm). For that reason, the content of hydrogen in the lower insulating layer 22a is sufficiently smaller than in a situation where the passivation layer consists of a single SiNx layer as in the conventional configuration. Meanwhile, the upper insulating layer 22b to be formed on the lower insulating layer 22a is formed out of an SiOx layer, of which the hydrogen content is even smaller than that of the lower insulating layer 22b. Consequently, the overall hydrogen content of the passivation layer 22 is small.

As can be seen, the passivation layer 22 has a configuration in which the lower and upper insulating layers 22a and 22b are stacked one upon the other, and its hydrogen content is not uniform in the thickness direction. That is to say, a portion of the passivation layer 22 which is located closer to the source and drain electrodes 14, 16 is a region with the higher hydrogen content, while the rest of the passivation layer 22 which is located more distant from the source and drain electrodes 14, 16 is a region with the lower hydrogen content.

Also, in the passivation layer 22 with such a structure, the lower insulating layer 22a which contacts with the source and drain electrodes 14, 16 is formed out of a silicon-based insulating layer with a high nitrogen concentration (or including nitrogen but not including oxygen), while the upper insulating layer 22b is formed out of a silicon-based insulating layer with a high oxygen concentration (or including oxygen but not including nitrogen).

Optionally, the passivation layer 22 may include a silicon oxynitride (SiOxNy, where x>y) layer or a silicon nitride oxide (SiNxOy, where x>y) layer. In that case, the closer to the source and drain electrodes 14, 16, the higher the nitrogen concentration of the passivation layer 22 should be. However, the passivation layer 22 does not have to be comprised of two layers as in this embodiment, but may also be comprised of three or more layers.

Over the passivation layer 22, formed is an interlayer insulating layer 24 which is typically made of an organic resin material. The interlayer insulating layer 24 not only secures electrical insulation between layers but also functions as a layer that planarizes the surface of the substrate.

On the interlayer insulating layer 24, arranged is a lower transparent electrode 32 made of ITO or IZO. The lower transparent electrode 32 has a hole 32H and is formed so as to be electrically insulated from the TFT 5 (or the drain electrode 16). Over the lower transparent electrode 32, arranged is an upper transparent electrode 30 of ITO or IZO with a dielectric layer (insulating layer) 26 interposed between them.

The lower transparent electrode 32 may function as a common electrode, for example. On the other hand, the upper transparent electrode 30 may function as a pixel electrode, for example. A storage capacitor is formed by the lower transparent electrode 32, the upper transparent electrode 30 and the dielectric layer 26 interposed between them. If a storage capacitor is formed by using the lower transparent electrode 32 in this manner, there is no need to provide any storage capacitor line on the same layer as the gate line 2, and therefore, the aperture ratio can be increased.

Through the interlayer insulating layer 24 and the dielectric layer 26, a contact hole CH has been cut to reach the surface of the drain electrode 16 of the TFT 5 (or a drain contact portion 16′ as an extension of the drain electrode 16). Also, inside the hole 32H of the lower transparent electrodes 32, a transparent connecting portion 32C is arranged inside the contact hole CH independently of the lower transparent electrode 32. The drain electrode 16 and the upper transparent electrode (pixel electrode) 30 are electrically connected together inside the contact hole CH via the transparent connecting portion 32C.

Meanwhile, as shown in FIG. 3(b), in the peripheral area 110 of the TFT substrate 100, arranged is a gate line terminal portion 2T which has been formed in the same process step as the gate electrode 12 and the gate line 2. Inside the contact hole that runs through the gate insulating film 20, etch stop layer 21, passivation layer 22, interlayer insulating layer 24 and dielectric layer 26, the gate line terminal portion 2T is connected to a transparent connecting terminal portion 30T on the same layer as the upper transparent electrode 30 via the transparent connecting portion 32T on the same layer as the lower transparent electrode 32.

The TFT substrate 100 with such a configuration is used in a liquid crystal display device. By injecting and sealing a liquid crystal layer between the TFT substrate 100 and a counter substrate (not shown), a liquid crystal display device can be obtained.

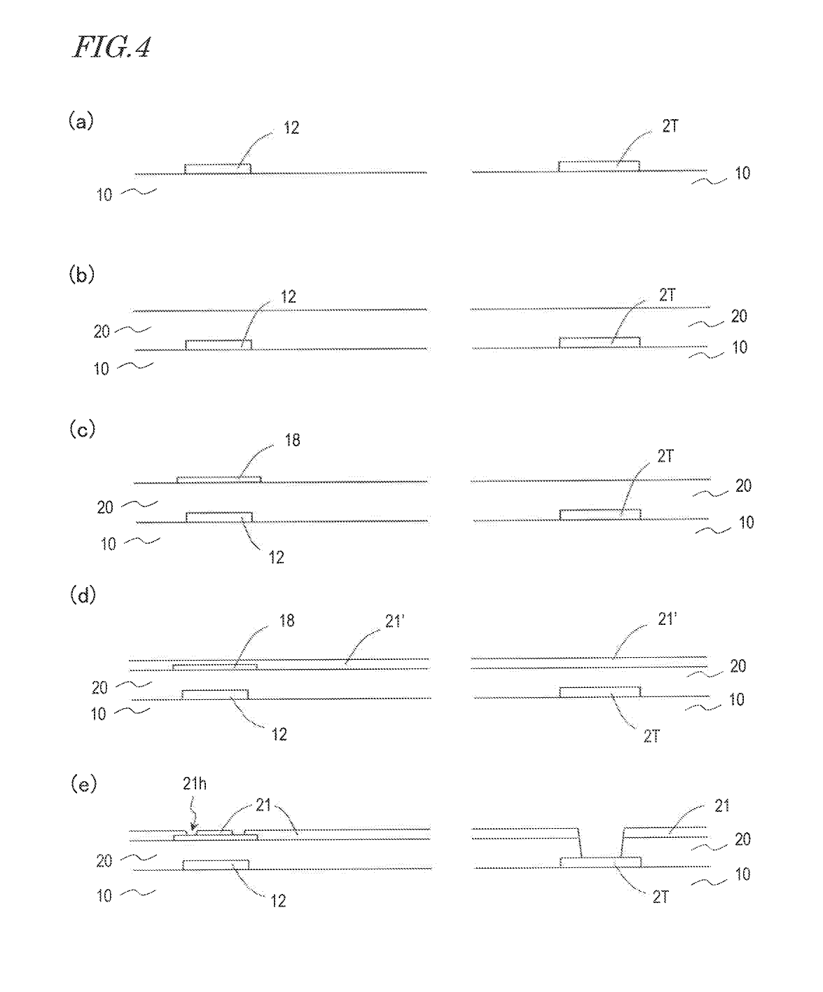

Next, it will be described with reference to FIGS. 4 through 6 how to fabricate the TFT substrate 100 of the first embodiment shown in FIGS. 2, 3(a) and 3(b).

FIGS. 4(a) through 4(e), FIGS. 5(f) through 5(i) and FIGS. 6(j) through 6(l) illustrate respective manufacturing process steps to fabricate the TFT substrate 100. On the left-hand side of these drawings, illustrated is a region in the vicinity of the TFT shown in FIG. 3(a). On the other hand, on the right-hand side of these drawings, illustrated is a region in the vicinity of the terminal portion shown in FIG. 3(b).

First of all, as shown in FIG. 4(a), a substrate 10 is provided. The substrate 10 may be a glass substrate, a silicon substrate, or a plastic or resin substrate with thermal resistance. Examples of the plastic or resin substrates include substrates made of polyethylene terephthalate (PET), polyethylene naphthalate (PEN), polyether sulfone (PES), an acrylic resin, and a polyimide resin.

Next, a conductive film to be a gate line 12 and other members is deposited to a thickness of 50 nm to 300 nm over the substrate 10. The conductive film may be made of a metallic element selected appropriately from the group consisting of aluminum (Al), tungsten (W), molybdenum (Mo), Ta (tantalum), Cr (chromium), Ti (titanium), and Cu (copper) or an alloy or metal nitride thereof. Or the conductive film may also be a stack of multiple layers of any of these metallic elements.

In this embodiment, a stack of conductive films consisting of an aluminum (Al) layer as the lower layer and a molybdenum-niobium (MoNb) alloy as the upper layer (of which the thicknesses are approximately 200 nm and 100 nm, respectively) is formed by sputtering process, and then patterned into an intended shape by photolithographic process using a resist mask, thereby forming a gate electrode 12. As a result of this process step, a gate line 2 and a gate line terminal portion 2T (see FIG. 2) are also formed.

Thereafter, as shown in FIG. 4(b), a gate insulating film 20 is formed over the gate electrode 12 by plasma CVD process, for example. The gate insulating film 20 may be formed appropriately out of a silicon oxide (SiOₓ) layer, a silicon nitride (SiNₓ) layer, a silicon oxynitride (SiOₓN_{y}, where x>y) layer, or a silicon nitride oxide (SiNₓO_{y}, where x>y) layer, for example.

Optionally, the gate insulating layer 20 may have a multilayer structure. To prevent dopants from diffusing from the substrate 10, a lower gate insulating layer may be provided. The lower gate insulating film may be formed out of a silicon nitride layer or a silicon nitride oxide layer, for example. On the other hand, the upper gate insulating layer may be formed out of a silicon oxide layer or a silicon oxynitride layer, for example. To form a dense gate insulating film with little gate leakage current at a lower deposition temperature, a rare gas element such as argon may be added to the reactive gas so as to be introduced into the gate insulating layer. In this embodiment, a silicon nitride layer was deposited to a thickness of 100 nm to 400 nm with SiH₄ and NH₃ gases used as reactive gases.

Thereafter, as shown in FIG. 4(c), an oxide semiconductor film is deposited by sputtering process to a thickness of 30 to 100 nm over the gate insulating layer 20 and then etched and patterned into a predetermined shape (typically into islands) by photolithographic process using a resist mask, thereby obtaining an oxide semiconductor layer 18. Optionally, the oxide semiconductor layer 18 thus formed may be subjected to oxygen plasma processing. The oxide semiconductor layer 18 suitably has a thickness of about 30 nm to about 100 nm, and may have a thickness of 50 nm, for example.

In this example, the oxide semiconductor layer 18 is obtained by patterning an In—Ga—Zn—O based amorphous oxide semiconductor film including In, Ga and Zn at a ratio of one to one to one, for example. However, In, Ga and Zn do not have to have the ratio described above but may also have any other appropriately selected ratio. Alternatively, the oxide semiconductor layer 18 may also be made of another oxide semiconductor film, instead of the In—Ga—Zn—O based semiconductor film.

More specifically, examples of other oxide semiconductor films include an InGaO₃(ZnO)₅ film, a magnesium zinc oxide (MgₓZn₁₋ₓO) film, a cadmium zinc oxide (CdₓZn₁₋ₓO) film and a cadmium oxide (CdO) film. Still alternatively, the oxide semiconductor layer 18 may also be formed out of a ZnO film to which one or multiple dopant elements selected from the group consisting of Group I, Group XIII, Group XIV, Group XV and Group XVII elements have been added, or may naturally be a ZnO film to which no dopant elements have been added at all. The ZnO film may be in an amorphous state, a polycrystalline state, or a microcrystalline state (which is a mixture of amorphous and polycrystalline states).

If an amorphous In—Ga—Zn—O based semiconductor film is used as a material for the oxide semiconductor layer 18, the oxide semiconductor layer 18 can be formed at a low temperature and high mobility can be achieved. The amorphous In—Ga—Zn—O based semiconductor film may be replaced with an In—Ga—Zn—O based semiconductor film which exhibits crystallinity with respect to a predetermined crystal axis (C-axis).

The top layer of the gate insulating layer 20 (i.e., the layer that contacts with the oxide semiconductor layer 18) is suitably an oxide layer (such as an SiO₂ layer). In that case, even if there are oxygen deficiencies in the oxide semiconductor layer 18, the oxygen deficiencies can be covered by oxygen included in the oxide layer. As a result, such oxygen deficiencies of the oxide semiconductor layer 18 can be reduced effectively.

Subsequently, an insulating layer 21′ may be formed out of an SiOx film, for example, so as to cover the oxide semiconductor layer 18 as shown in FIG. 4(d). Thereafter, as shown in FIG. 4(e), the insulating layer 21′ is patterned, thereby forming an etch stop layer 21 including a portion which covers the channel region of the oxide semiconductor layer 18. As described above, the etch stop layer 21 is suitably made of an oxide layer, because the oxygen deficiencies of the oxide semiconductor layer 18 can be reduced effectively. In the embodiment illustrated in FIG. 4, the etch stop layer 21 has a pair of holes 21h which are arranged to face two opposing sides of an island of the oxide semiconductor layer 18 (see FIG. 2). Inside these holes 21h, the oxide semiconductor layer 18 is exposed. However, this embodiment is only an example and any other embodiment may also be adopted. For example, the etch stop layer 21 may also be provided as islands to cover only the channel region of the oxide semiconductor layer 18.

Meanwhile, in the peripheral area, while this process step of forming an etch stop layer 21 is being performed, the gate insulating film 20 and insulating film 21′ are etched away from over the gate line terminal portion 2T and the surface of the gate line terminal portion 2T gets exposed.

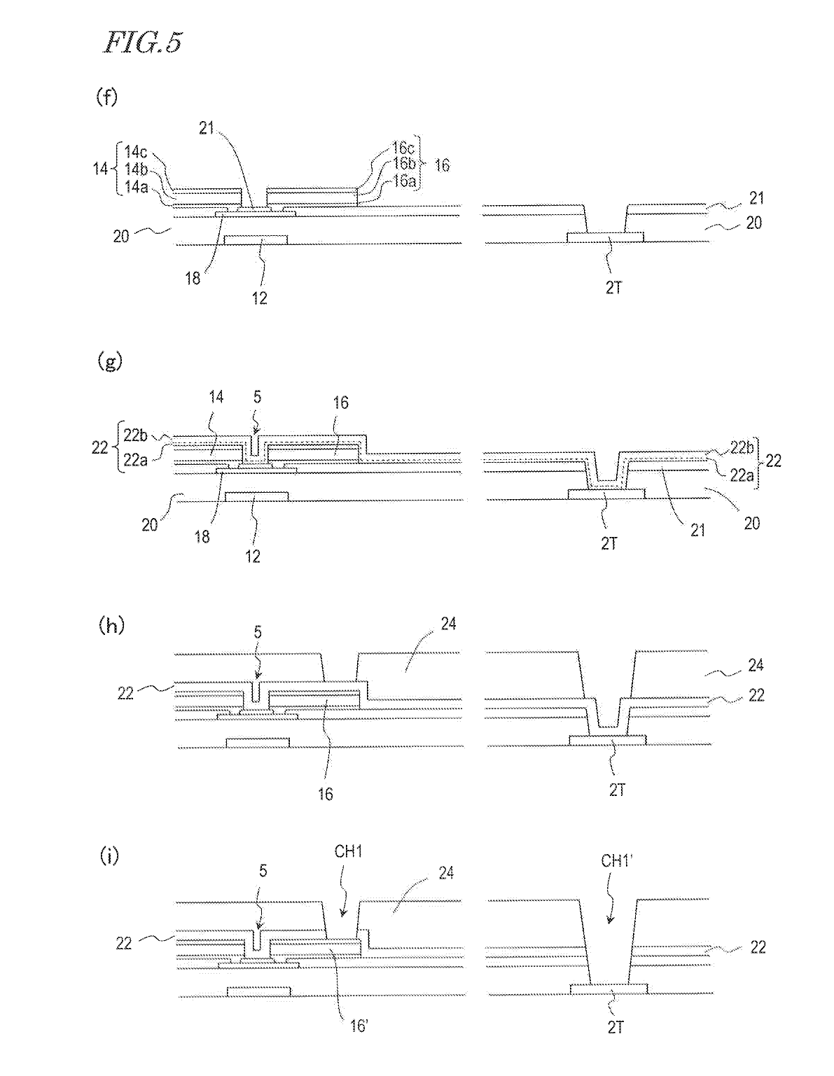

After that, as shown in FIG. 5(f), the conductive film formed by sputtering process, for example, is patterned into a predetermined shape by photolithographic process, thereby forming source and drain electrodes 14, 16. In this process step, a source line 4 and a source line terminal portion 4T (see FIG. 2) are also formed simultaneously.

In this embodiment, the source and drain electrodes 14 and 16 have been formed to have a triple layer structure consisting of MoN, Al and MoN layers (i.e., the lowermost MoN layer 14a, 16a, the middle Al layer 14b, 16b, and the uppermost MoN layer 14c, 16c). The lowermost MoN layer 14a, 16a may have a thickness of 30 nm to 70 nm, for example. The middle Al layer 14b, 16b may have a thickness of 100 nm to 250 nm, for example. And the uppermost MoN layer 14c, 16c may have a thickness of 50 nm to 150 nm. The lower MoN layer 14a, 16a suitably has higher nitrogen content than the upper MoN layer 14c, 16c. If the source and drain electrodes 16, 18 have such a structure, the source and drain electrodes 14 and 16 can have a tapered cross-sectional shape.

As a conductive material to make the source and drain electrodes 14, 16, molybdenum (Mo), copper (Cu), titanium (Ti), aluminum (Al) or any other suitable metal or an alloy or a metal nitride thereof may be used appropriately. Optionally, the source and drain electrodes 14 and 16 may include a layer which is made of a material with a light transmitting property such as indium tin oxide (ITO), indium zinc oxide (IZO), indium tin oxide including silicon dioxide (ITSO), indium oxide (In₂O₃), tin oxide (SnO₂), zinc oxide (ZnO) or titanium nitride. Typically, however, the surface of the source and drain electrodes 14, 16 is made of a material including Mo, Ti, Cu or Al (such as MoN).

Also, the etching process to be performed in the photolithographic process to form the source and drain electrodes 14, 16 may be either a dry etching process or a wet etching process. To process a substrate with a large area, however, a dry etching process which will cause a little variation in line width or size is suitably adopted. When this etching process step is performed, the etch stop layer 21 has already been formed on the oxide semiconductor layer 18, and therefore, it is possible to prevent the oxide semiconductor layer 18 from getting etched unintentionally.

Next, as shown in FIG. 5(g), a passivation layer 22 is formed as a protective insulating layer so as to cover the TFT 5. The process step of forming a passivation layer 22 includes the steps of forming an insulating region including nitrogen to a thickness of more than 0 nm to equal to or smaller than 30 nm so that the region contacts with the source and drain electrodes 14, 16 and then forming an insulating region including oxygen to a thickness of more than 30 nm. More specifically, the process step of forming the passivation layer 22 includes the steps of forming a silicon nitride layer (lower insulating layer) 22a to a thickness of 30 nm or less and stacking a silicon oxide layer (upper insulating layer) 22b to a thickness of more than 30 nm on the silicon nitride layer 22a.

The silicon nitride layer 22a may be formed by plasma CVD process, for example, using a mixture of SiH₄, NH₃ and N₂ gases as a reactive gas. On the other hand, the silicon oxide layer 22b may be formed by plasma CVD process, for example, using a mixture of SiH₄ and N₂O gases as a reactive gas. Alternatively, at least one of the silicon nitride layer 22a and silicon oxide layer 22b may be formed by sputtering process.

In this example, the silicon nitride layer 22a is formed so as to have a thickness of more than 0 nm to equal to or smaller than 30 nm. The thickness of the silicon nitride layer 22a can be controlled easily by adjusting the film deposition process time. The silicon nitride layer 22a more suitably has a thickness of 2 nm to 10 nm. On the other hand, the silicon oxide layer 22b is formed to be thicker than the silicon nitride layer 22a, and suitably has a thickness of 50 nm to 400 nm, more suitably 100 nm to 300 nm.

Optionally, the passivation layer 22 may include a silicon oxynitride (SiOxNy, where x>y) layer or a silicon nitride oxide (SiNxOy, where x>y) layer. In that case, the passivation layer 22 is suitably formed so that the closer to the source and drain electrodes 14, 16, the higher its nitrogen concentration gets. The passivation layer 22 does not have to be comprised of two layers as described above, but may also be comprised of three or more layers.

By subjecting the entire substrate to a heat treatment (annealing process) at approximately 350° C. after the passivation layer 22 including multiple regions of different film qualities in the thickness direction has been formed and before an interlayer insulating layer 24 (to be described later) is formed, the device characteristic and reliability of the TFT can be improved. If the heat treatment is carried out at this timing, it is possible to prevent the surface of the source and drain electrodes 14, 16 which is covered with the passivation layer 22 from getting oxidized and coming to have increased wiring resistance. In addition, by carrying out the heat treatment before the interlayer insulating layer 24 is formed, even if oxygen deficiencies have been produced in the channel region of the oxide semiconductor layer 18, those oxygen deficiencies can be oxidized and easily reduced. As a result, intended TFT performance is realized easily.

Since the silicon nitride layer 22a is in contact with the upper layer 14c, 16c of the source and drain electrodes during this heat treatment, it is possible to prevent a metal oxide film from being formed on the surface (i.e., on the upper layer 14c, 16c) of the source and drain electrodes. As a result, a decrease in the closeness of contact of the passivation layer 22 can be minimized. In addition, since the silicon nitride layer 22a is a thin layer and is comprised mostly of the silicon oxide layer 22b, the passivation layer 22 has so small hydrogen content that the influence of hydrogen on the back channel of the oxide semiconductor layer 18 can be only a little. Consequently, even after having been subjected to the aging treatment, the threshold value of the TFT hardly shifts and it is possible to prevent OFF-state leakage current or shortage of ON-state current from deteriorating the display quality of the panel.

The heat treatment temperature is not particularly limited but typically falls within the range of 230° C. to 480° C., and suitably falls within the range of 250° C. to 350° C. The heat treatment process time is not particularly limited, either, but may be 30 to 120 minutes, for example. Depending on the material of the interlayer insulating layer 24, the heat treatment may be carried out after the interlayer insulating layer 24 has been formed.

Subsequently, as shown in FIG. 5(h), an interlayer insulating layer (planarizing layer) 24 of a photosensitive resin film or any other suitable material is formed on the passivation layer 22. The interlayer insulating layer 24 is suitably made of an organic material. A hole has been cut through the interlayer insulating layer 24 and over a drain contact portion 16′ which is an extended portion of the drain electrode 16. Meanwhile, in the peripheral area, holes are created over the gate line terminal portion 2T and over the source line terminal portion 4T (not shown).

Thereafter, as shown in FIG. 5(i), by etching the passivation layer 22 using the interlayer insulating layer 24 with holes as a mask, a contact hole CH1 is created to reach the extended portion of the drain electrode 16 (i.e., the drain contact portion 16′). In addition, a contact hole CH1′ reaching the gate line terminal portion 2T (and the source line terminal portion 2T) is also created.

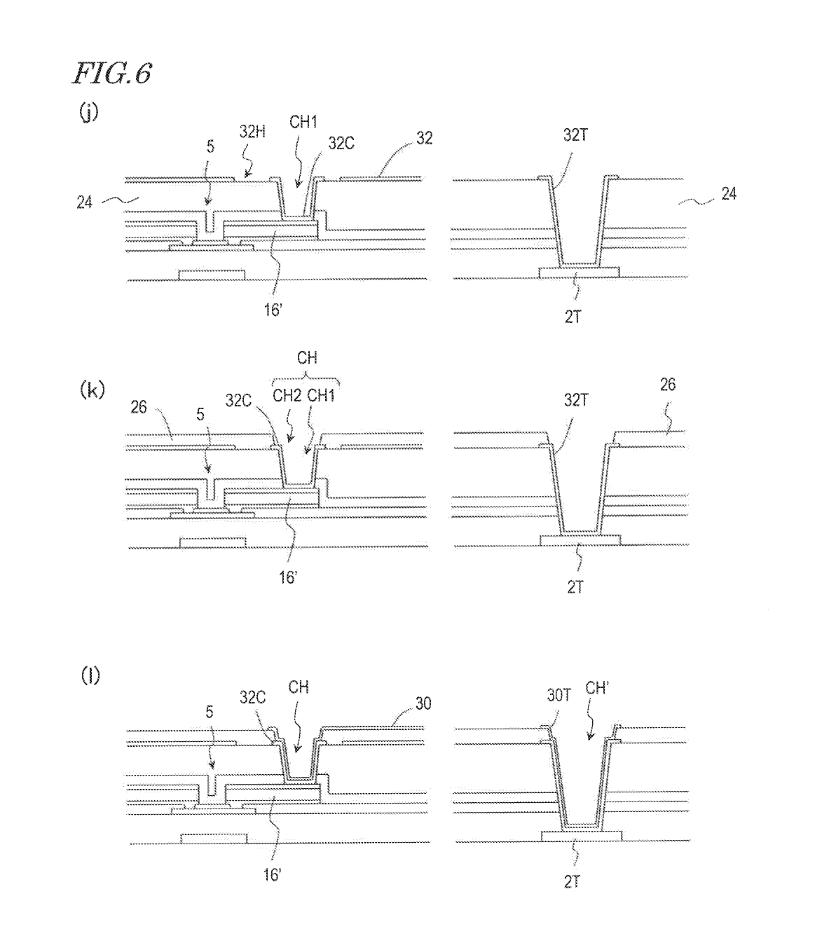

After that, as shown in FIG. 6(j), by patterning a transparent conductive film of ITO, IZO or any other suitable material, a lower transparent electrode 32 is formed on the interlayer insulating layer 24. At the same time, a transparent connecting portion 32C separated from the lower transparent electrode 32 is formed so as to contact with the drain contact portion 16′ which is exposed inside the contact hole CH1. The transparent connecting portion 32C may cover the sidewall of the contact hole CH1, for example. Meanwhile, in the peripheral area, a transparent connecting portion 32T is formed so as to contact with the gate line terminal portion 2T (and the source line terminal portion 4T) inside the contact hole CH1′.

Thereafter, as shown in FIG. 6(k), a dielectric layer 26 is deposited over the entire surface of the substrate to cover the lower transparent electrode 32 and other members, and then another contact hole CH2 is cut through the dielectric layer 26 so as to overlap with the contact hole CH1 that has already been cut. In this manner, a contact hole CH which makes it connectible to the drain contact portion 16′ of the TFT 5 is obtained.

The dielectric layer 26 is obtained by forming a silicon nitride film or silicon oxide film to a thickness of 100 nm to 300 nm by sputtering process or CVD process. Alternatively, the dielectric layer 26 may also be formed out of a silicon nitride oxide film or a silicon oxynitride film. The etching process to cut the contact hole CH2 may be performed by photolithographic process.

Subsequently, as shown in FIG. 6(l), by patterning the transparent conductive film of ITO, IZO or any other suitable material, an upper transparent electrode (pixel electrode) 30 is formed on the dielectric layer 26. Meanwhile, in the peripheral area, a transparent connecting portion 30T which is connected to the gate line terminal portion 2T (and source line terminal portion 4T) inside the contact hole CH′ is formed.

The upper transparent electrode 30 is electrically connected to the drain contact portion 16′ via the transparent connecting portion 32C inside the contact hole CH. The upper transparent electrode 30 is typically formed on a pixel-by-pixel basis so as to cover entirely the area surrounded with the gate line 2 and the source line 4.

The TFT substrate 100 thus obtained can be used effectively as an active-matrix substrate for a liquid crystal display device. Optionally, the shape of the pixel electrode 30 may be selected appropriately depending on the display mode. For example, if the pixel electrode 30 is formed so as to include a plurality of elongate electrodes that run parallel to each other and if an oblique electric field is generated between the pixel electrode 30 and the lower transparent electrode 32, the TFT substrate 100 can also be used in a liquid crystal display device which operates in the FFS mode. Naturally, either a vertical or horizontal alignment film may be provided over the pixel electrode 30 depending on the display mode.

A TFT substrate 100 including an oxide semiconductor TFT has been described as a semiconductor device according to a first embodiment. By using this TFT substrate 100, a display device of good display quality can be fabricated at a good yield.

### Embodiment 2

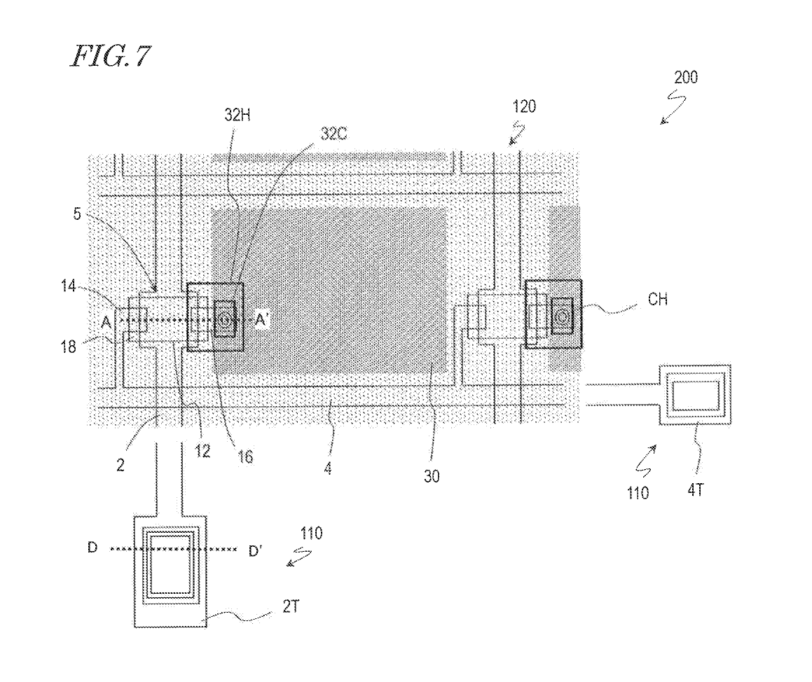

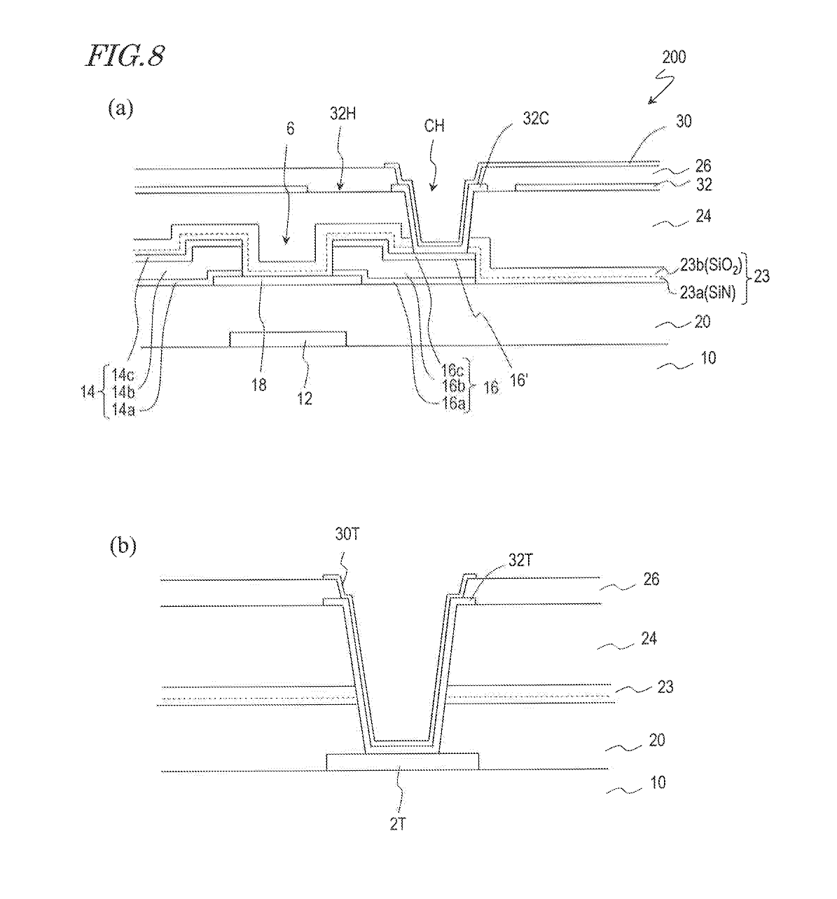

FIG. 7 and FIGS. 8(a) and 8(b) illustrate a TFT substrate 200 as a second embodiment. In the TFT substrate 200 of this embodiment, no etch stop layer 24 is provided on the oxide semiconductor layer 18, which is a difference from the TFT substrate 100 of the first embodiment. That is to say, the TFT substrate 200 of this embodiment includes a TFT 6 of a channel-etched type. In the following description, any component having substantially the same function as its counterpart of the first embodiment will be identified by the same reference numeral as its counterpart's and a detailed description thereof will be omitted herein.

As shown in FIGS. 8(a) and 8(b), in this TFT substrate 200, a passivation layer 23 which covers the TFT 6 is arranged so as to contact with not only the source and drain electrodes 14, 16 but also the channel region of the oxide semiconductor layer 18 as well.

Just like the passivation layer 22 of the first embodiment, the passivation layer 23 of this embodiment is also comprised of a lower insulating layer 23a and an upper insulating layer 23b which is arranged on the lower insulating layer 23a. The lower insulating layer 23a is formed out of a silicon nitride (SiNx) layer with a thickness of more than 0 nm to equal to or smaller than 30 nm, and the upper insulating layer 23b is formed out of a silicon oxide (SiOx) layer with a thickness of more than 30 nm.

The lower insulating layer 23a is formed out of a silicon nitride layer, and therefore, typically includes some hydrogen. However, the thickness of this lower insulating layer 23a is 30 nm or less as described above, and is much smaller than that of an ordinary passivation layer 23 (which usually falls within the range of 100 to 400 nm). For that reason, the content of hydrogen in the lower insulating layer 23a is sufficiently smaller than in a situation where the passivation layer 23 consists of a single SiNx layer as in the conventional configuration. Meanwhile, the upper insulating layer 23b to be formed on the lower insulating layer 23a is formed out of an SiOx layer, of which the hydrogen content is even smaller than that of the lower insulating layer 23a. Consequently, the overall hydrogen content of the passivation layer 23 is small.

As can be seen, even if the passivation layer 23 contacts with the channel region of the oxide semiconductor layer 18, diffusion of hydrogen into the oxide semiconductor layer 18 does not affect the TFT's performance so seriously, because the lower insulating layer 23a is a thin layer. That is why an oxide semiconductor TFT 6 with good device performance can be obtained as in the first embodiment described above.

In addition, since the silicon nitride layer as the lower insulating layer 23a contacts with the source and drain electrodes 14, 16, the closeness of contact does not decrease even during the heat treatment, and the TFT substrate 200 can be manufactured at a good yield with film occurrence of film peeling prevented.

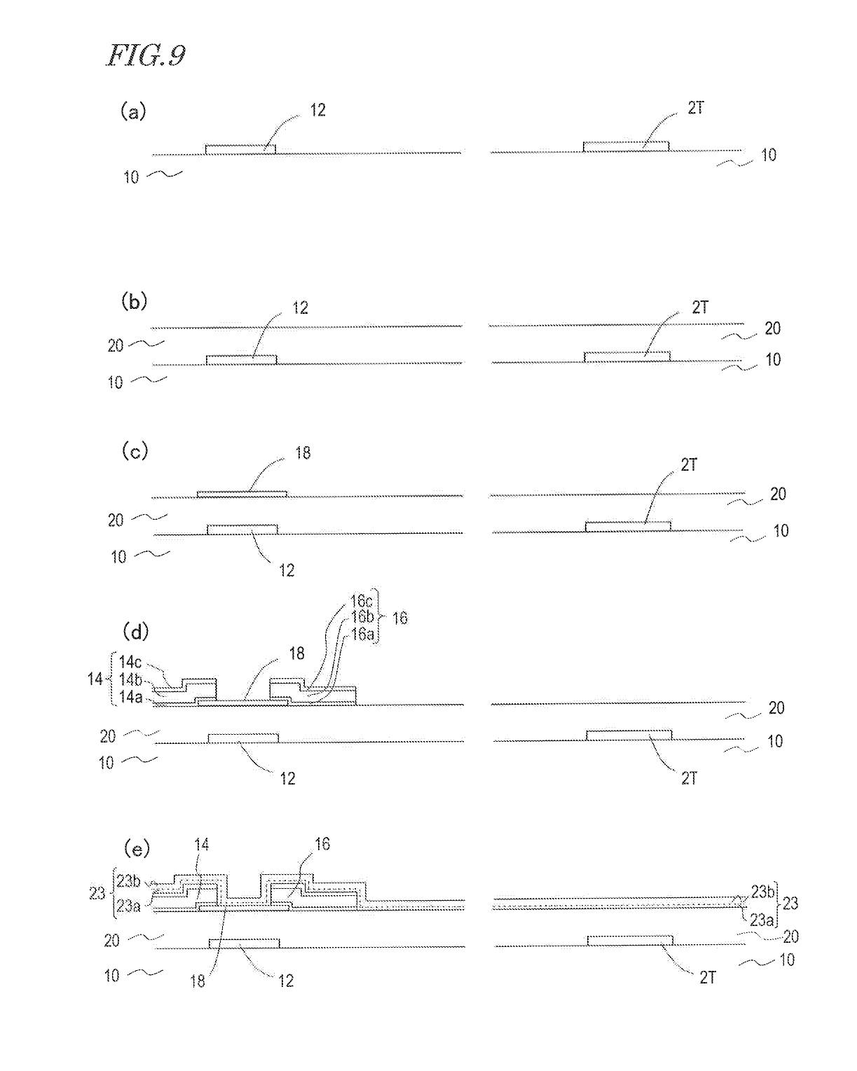

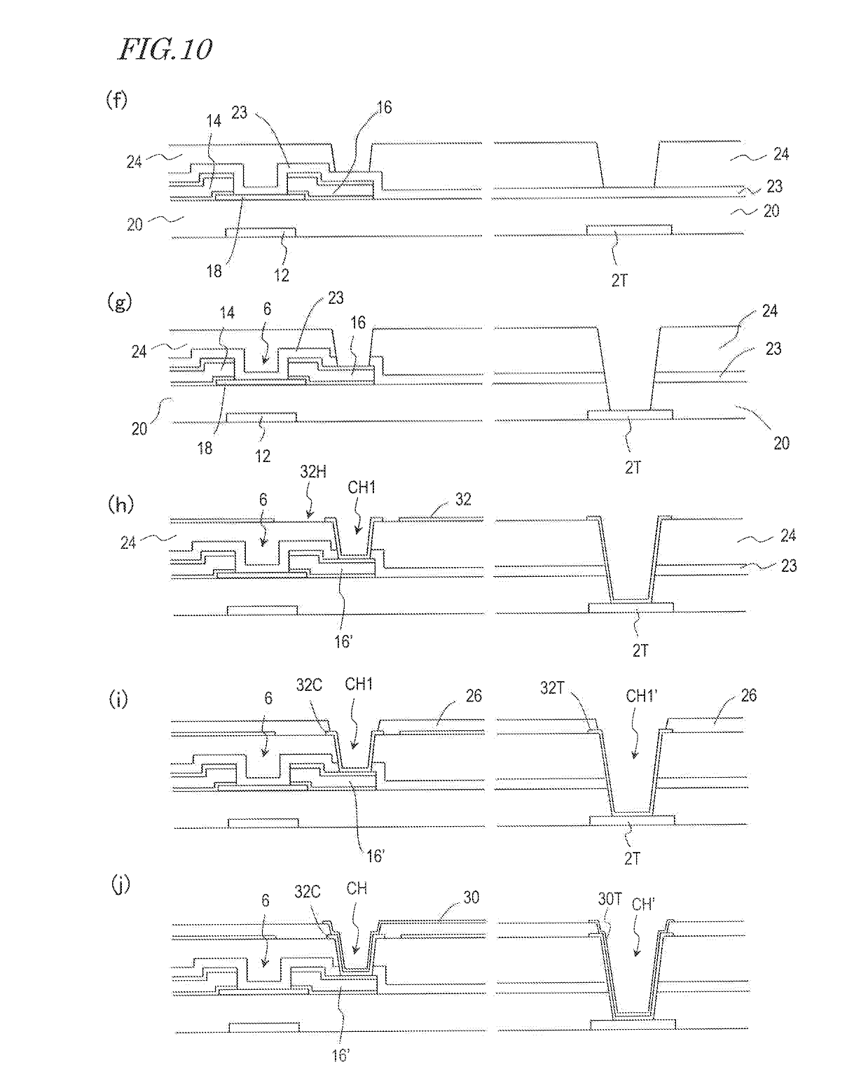

FIGS. 9(a) to 9(e) and FIGS. 10(f) to 10(j) illustrate manufacturing process steps to fabricate the TFT substrate 200. The process steps shown in FIGS. 9(a) to 9(c) are the same as the manufacturing process steps of the first embodiment shown in FIGS. 4(a) to 4(c), respectively, and description thereof will be omitted herein.

As shown in FIG. 9(d), according to this embodiment, after the oxide semiconductor layer 18 has been formed, source and drain electrodes 14, 16 are formed separately from each other so as to be connected to the oxide semiconductor layer 18 with no etch stop layer 21 provided between them. As can be seen, since there is no need to perform the process step of forming an etch stop layer 21, the manufacturing process can be simplified compared to the first embodiment.

Nevertheless, if an etching process is carried out to separate the source and drain electrodes from each other in the process step shown in FIG. 9(d), the channel region of the oxide semiconductor layer 18 could be over-etched. In addition, as the conductive film to make the source and drain electrodes 14, 16 directly contacts with the channel region of the oxide semiconductor layer 18, the metallic element included in the metal film that forms the bottom of this conductive film could diffuse toward and enter the oxide semiconductor layer 18.

It should be noted that the structure and material of the source and drain electrodes 14, 16 may be the same as those of the first embodiment described above. The surface of the source and drain electrodes 14, 16 is typically made of a material including Mo, Ti, Cu or Al (such as MoN).

Thereafter, a passivation layer 23 is formed as shown in FIG. 9(e). Since no etch stop layer is provided in this embodiment, the passivation layer 23 is formed to contact with the source and drain electrodes 14, 16 and the oxide semiconductor layer 18.

After that, a heat treatment is carried out as in the first embodiment, and the device performance of the TFT 6 can be improved as a result. Since the silicon nitride layer 23a is in contact with the upper layer 14c, 16c of the source and drain electrodes in this process step, it is possible to prevent a metal oxide film from being formed on the surface of the source and drain electrodes. As a result, a decrease in the closeness of contact of the passivation layer 23 can be minimized. In addition, since the silicon nitride layer 23a is a thin layer, the influence of hydrogen on the back channel of the oxide semiconductor layer 18 can be only a little.

The process steps shown in FIGS. 10(f) to 10(j) to be performed after that are substantially the same as the process steps shown in FIGS. 5(h), 5(g) and FIGS. 6(j) to 6(l), and description thereof will be omitted herein. However, since no etch stop layer is provided, there is no need to etch the etch stop layer when a contact hole CH1′ is cut in the peripheral area, which is a difference from the first embodiment.

By using a TFT substrate 200 thus obtained, a display device of good display quality can be fabricated at a good yield.

Even though some embodiments of the present invention have been described above, those embodiments are naturally modifiable in various manners. For example, although a bottom-gate-type TFT, of which the gate electrode is arranged under a semiconductor layer, has been described, the present invention is also applicable to a TFT with a top gate structure. In a TFT with the top gate structure, a protective insulating layer (passivation layer) is also arranged so as to cover metallic lines and electrodes. Thus, by providing a silicon nitride layer with a thickness of 30 nm or less in a region of the passivation layer which contacts with the metallic lines and then stacking a silicon oxide layer thereon, a good device characteristic is realizable with film peeling eliminated. Also, in the embodiments described above, the upper surface of the semiconductor layer contacts with the source and drain electrodes. However, the present invention is also applicable to a TFT with a bottom-contact structure which is obtained by forming source and drain electrodes first and then forming islands of semiconductor layer over the source and drain electrodes.

Also, although an active-matrix substrate for use in a liquid crystal display device has been described, an active-matrix substrate for use to make an organic EL display device may also be fabricated. In an organic EL display device, a light-emitting element which is provided for each pixel includes an organic EL layer, a switching TFT and a driver TFT. And a semiconductor device according to an embodiment of the present invention can be used as any of those TFTs. Furthermore, by arranging those TFTs as an array and using them as select transistors, a storage element (i.e., an oxide semiconductor thin-film memory) can also be formed. The present invention is also applicable to an image sensor.

### INDUSTRIAL APPLICABILITY

A semiconductor device according to an embodiment of the present invention and a method for fabricating such a device can be used effectively as a TFT substrate for a display device and a method for fabricating such a device, for example.

### REFERENCE SIGNS LIST

2 gate line
4 source line
5, 6 TFT (oxide semiconductor TFT)
10 substrate
12 gate electrode
14 source electrode
16 drain electrode
18 oxide semiconductor layer
20 gate insulating layer
21 etch stop layer
22 passivation layer
22a lower insulating layer (silicon nitride layer)
22b upper insulating layer (silicon oxide layer)
24 interlayer insulating layer (planarizing layer)
26 dielectric layer
30 upper transparent electrode (pixel electrode)
32 lower transparent electrode (common electrode)
100, 200 TFT substrate
110 peripheral area
120 display area

1. A semiconductor device comprising:
a substrate;
a gate electrode formed on the substrate;
a gate insulating layer formed over the gate electrode;
an oxide semiconductor layer formed on the gate insulating layer;
source and drain electrodes electrically connected to the oxide semiconductor layer; and
an insulating layer formed over the source and drain electrodes,
wherein the insulating layer includes a silicon nitride layer which contacts with at least a part of the upper surface of the source and drain electrodes and of which the thickness is greater than 0 nm and equal to or smaller than 30 nm, and
a silicon oxide layer which is formed on the silicon nitride layer and of which the thickness is greater than 30 nm.

2. The semiconductor device of claim 1, wherein the silicon oxide layer has a thickness of 50 nm to 400 nm.

3. The semiconductor device of claim 1, wherein the upper surface of the source and drain electrodes that contacts with the silicon nitride layer is made of a conductive material including at least one element selected from the group consisting of Mo, Ti, Cu and Al.

4. The semiconductor device of claim 3, wherein the contact surface of the source and drain electrodes is made of molybdenum nitride.

5. The semiconductor device of claim 1, further comprising an etch stop layer which has been formed over a channel region of the oxide semiconductor layer.

6. The semiconductor device of claim 1, wherein the oxide semiconductor layer is made of an In—Ga—Zn—O based semiconductor.

7. A method for fabricating a semiconductor device, the method comprising the steps of:
(a) providing a substrate;
(b) forming a gate electrode on the substrate;
(c) forming an oxide semiconductor layer over the substrate so that the oxide semiconductor layer is insulated from the gate electrode and faces the gate electrode;
(d) forming source and drain electrodes to be connected to the oxide semiconductor layer on the substrate;
(e) forming an insulating layer which contacts with at least a part of the upper surface of the source and drain electrodes over the substrate; and
(f) conducting a heat treatment at a temperature of 230° C. to 480° C. after the step (e) has been performed,
wherein the step (e) includes the steps of:
forming a first insulating region including nitrogen so that the first insulating region contacts with the source and drain electrodes and has a thickness of more than 0 nm to equal to or smaller than 30 nm; and
forming a second insulating region including oxygen over the first insulating region so that the second insulating region has a thickness of more than 30 nm.

8. The method of claim 7, wherein the first insulating region is formed out of a silicon nitride layer and the second insulating region is formed out of a silicon oxide layer.

9. The method of claim 7, wherein the step (d) includes forming the surface of the source and drain electrodes out of a conductive material including at least one element selected from the group consisting of Mo, Ti, Cu and Al.

10. The method of claim 8, wherein the step of forming the silicon nitride layer in the step (e) is performed by a plasma CVD process using source gases including SiH₄ and NH₃ gases.

11. The method of claim 7, wherein the oxide semiconductor layer is made of an In—Ga—Zn—O based semiconductor.
